(19) United States
(12) Patent Application Publication
(10) Pub. No.: US 2018/0292469 A1
(43) Pub. Date: Oct. 11, 2018

(54) METHOD AND ARRANGEMENT FOR DETERMINING THE TRANSVERSE SENSITIVITY OF MAGNETIC FIELD SENSORS

(71) Applicant: FRAUNHOFER-GESELLSCHAFT ZUR FOERDERUNG DER ANGEWANDTEN FORSCHUNG E.V., Muenchen (DE)

(72) Inventors: HANS-PETER HOHE, Heiligenstadt (DE); VOLKER PETERS, Fuerth (DE)

(21) Appl. No.: 15/754,012

(22) PCT Filed: Aug. 22, 2016
(86) PCT No.: PCT/EP2016/069777

§ 371 Date: Feb. 21, 2018

(30) Foreign Application Priority Data
Aug. 26, 2015 (DE) 10 2015 216 262.1

(51) Int. Cl. G01R 33/00; G01R 33/07

(52) U.S. Cl. CPC G01R 33/0035; G01R 33/07; G01R 33/0017

(57) ABSTRACT

The present invention relates to a method and to a sensor arrangement for determining the transverse sensitivity of a magnetic field sensor or an arrangement of magnetic field sensors. The sensor, or the arrangement of sensors, has a defined direction of sensitivity here. In the method, one or more electrical conductors are applied to a substrate or integrated into the substrate in such a way that they generate a magnetic field at the location of the respective magnetic field sensor, of which magnetic field only one magnetic field component, which is perpendicular to the defined direction of sensitivity, contributes to a measurement signal or combined measurement signal of the magnetic field sensor or of the arrangement of magnetic field sensors. Therefore, the transverse sensitivity of the magnetic field sensor or of the arrangement of magnetic field sensors can be obtained by measuring this measurement signal.

### TECHNICAL FIELD

The present invention relates to a method and an arrangement for determining the transverse sensitivity of a magnetic field sensor or an arrangement of magnetic field sensors which are arranged on a substrate or integrated in a substrate, wherein the magnetic field sensor or arrangement of magnetic field sensors have a defined direction of sensitivity.

Magnetic field sensors are used in many technical application fields, in which the strength and/or direction of a magnetic field is to be determined at one location. One example is the detection of a position of two objects relative to each other, of which one object carries a magnetic field sensor and the other carries an element which generates a magnetic field.

### RELATED ART

Magnetic field sensors such as horizontal or vertical Hall elements often have a defined or specified direction of sensitivity, in which they usually exhibit the greatest measurement sensitivity. With magnetic field sensors of this kind, also called uniaxial magnetic field sensors, individual components of the vectorial magnetic field can be measured. Then, with suitable selection and arrangement of the sensors, the entire magnetic field vector can be determined from the measurement values of multiple uniaxial magnetic field sensors.

However, magnetic field sensors which have a defined direction of sensitivity may be transversely sensitive to interfering magnetic field components. They then display a measurement signal for magnetic field components which are perpendicular to their direction of sensitivity, albeit a very small signal. This transverse sensitivity may also vary from one sensor to another even if the sensors are of identical construction.

When magnetic field sensors are to be used for extremely accurate determination of magnetic field components, it is necessary to know the transverse sensitivity of the single sensors in order to be able to correct the measurement signal appropriately when magnetic field components transverse to the direction of sensitivity are present.

Previously, external coils which generate a magnetic field perpendicular to the direction of sensitivity were used to determine transverse sensitivity. These external coils must then be adjusted precisely to the respective magnetic field sensors, and where applicable also to each other. However, this involves a great deal of effort on the part of the user, and is prone to error.

The object of the present invention consists in describing a method and an arrangement for determining the transverse sensitivity of a magnetic field sensor or an arrangement of magnetic field sensors which enable an extremely accurate determination of transverse sensitivity without work-intensive adjustment requirements for the user.

### SUMMARY OF THE INVENTION

The object is solved with the method and the sensor arrangements of Claims 1, 2, 8 and 9. The method and sensor arrangement of Claims 1 and 8 relate to the determination of the transverse sensitivity of single magnetic field sensors, the method and arrangement of Claims 2 and 9 relate to the determination of the transverse sensitivity of an arrangement of multiple magnetic field sensors with a defined direction of sensitivity. Advantageous variations of the methods and the sensor arrangements are subject of the dependent claims or may be understood from the following description and exemplary embodiments.

In the suggested method for determining the transverse sensitivity of a magnetic field sensor which has a defined direction of sensitivity and is arranged on a substrate or integrated in a substrate, one or more electrical conductors are deposited on the substrate and/or integrated in the substrate, and generate(s) a magnetic field in response to a current flow. The conductor may be for example a simple strip conductor, an electrical conductor which has been shaped to form a coil, or even an electromagnet. The one or more electrical conductors are arranged and embodied in such manner that they generate one or more magnetic fields at the site of the magnetic field sensor, which magnetic field(s) either consist solely of a magnetic field component perpendicular to the defined direction of sensitivity, or of which only a magnetic field component perpendicular to the defined direction of sensitivity contributes to a measurement signal or combined measurement signal of the magnetic field sensor. The combined measurement signal may be for example a sum signal formed from temporally separate measurement or single signals. Then, a current flow of known magnitude is generated through the one or more electrical conductors, by which one or more magnetic fields with the magnetic field component perpendicular to the defined direction of sensitivity are generated at the location of the magnetic field sensor. The measurement signal induced in the magnetic field sensor by this magnetic field component is captured and from it is deduced the transverse sensitivity of the magnetic field sensor.

The suggested method may also be used with an arrangement of magnetic field sensors which returns a combined output signal from the measurement signals of the magnetic field sensors and exhibits a defined direction of sensitivity. Again, the magnetic field sensors are arranged on a substrate and/or integrated in a substrate. In this case too, one or more electrical conductors which generate a magnetic field in response to a current flow are deposited on the substrate and/or integrated in the substrate. The one or more electrical conductor(s) are arranged and embodied in such manner that they each generate one or more magnetic fields at the locations of the magnetic field sensors, of which only a magnetic field component perpendicular to the defined direction of sensitivity contributes to the output signal of the arrangement. The output signal perpendicular to the specified direction of sensitivity in the arrangement which is induced by the magnetic field component for a defined current flow through the one or more electrical conductors is again captured to enable the transverse sensitivity of the arrangement to be determined.

Of course, in both applications the one or more electrical conductors must be arranged in such manner that the magnetic field generated at the location of the magnetic field sensors when a current flow is passed through the one or more electrical conductors is is strong enough to be usable for determining the transverse sensitivity of the magnetic field sensor or of the arrangement of magnetic field sensors. Moreover, the size of this magnetic field at the location of the magnetic field sensors for the selected current flow must be known. This can be calculated with corresponding preliminary measurements or also deduced from the geometry and magnitude of the current flow. In the simplest case, when determining the transverse sensitivity of the arrangement of magnetic field sensors, the combination of measurement signals of the single magnetic field sensors merely involve adding the measurement signals from the individual sensors.

Accordingly, one of the two suggested sensor arrangements has at least one magnetic field sensor with a defined direction of sensitivity. The at least one magnetic field sensor is arranged on a substrate and/or integrated in a substrate together with one or more electrical conductors which generate one or more magnetic fields when a current flow is applied. In this context, the magnetic field sensor may for example be integrated in the substrate and the one or more electrical conductors may be deposited on the substrate. The one or more electrical conductors are arranged and embodied such that they are able to generate one or More magnetic fields at the location of the magnetic field sensor in response to a current flow, wherein either the one or more magnetic fields only have a magnetic field component perpendicular to the defined direction of sensitivity, or from which one or more magnetic fields only a magnetic field component perpendicular to the defined direction of sensitivity contributes to a measurement signal or combined measurement signal of the magnetic field sensor.

The second sensor arrangement accordingly comprises a plurality of magnetic field sensors, from whose measurement signals a combined output signal can be generated, for which the sensor arrangement has a defined direction of sensitivity. The magnetic field sensors are again arranged on a substrate and/or integrated in a substrate together with one or more electrical conductors which generate one or more magnetic fields in response to a current flow. The one or more electrical conductors are arranged and embodied such that they can each generate one or more magnetic fields at the locations of the magnetic field sensors, of which one or more magnetic fields only a magnetic field component perpendicular to the defined direction of sensitivity contributes to the output signal.

The effect of integrating or depositing the one or more electrical conductors for generating the magnetic field with which the transverse sensitivity of the magnetic field sensors or the arrangement of magnetic field sensors is to be determined in or on the substrate with the one or more magnetic field sensors is that an external coil or external magnetic field field generation is no longer necessary for determining transverse sensitivity. The electrical conductors may be specified and mounted on semiconductor substrates extremely precisely in terms of their geometry and arrangement with the aid of lithographic techniques, for example. Thus, a magnetic field with precisely specifiable strength can be generated at the location of the magnetic field sensor, such a magnetic field having the corresponding magnetic field component exactly perpendicular to the direction of sensitivity of the magnetic field sensor or the arrangement of magnetic field sensors. This enables transverse sensitivity to be determined extremely accurately, which in turn means that it can also be corrected accurately. The user no longer has to carry out any adjustment steps to determine transverse sensitivity. Moreover, the determination may either be performed in advance of a magnetic field measurement with the magnetic field sensors, or also during the measurement, and in both cases the magnetic field for determining transverse sensitivity is preferably generated as a magnetic alternating field. This makes it possible for the fraction of the measurement signal that is induced by this magnetic field component extending perpendicularly to the direction of sensitivity to be easily separated from other portions of the measurement signal.

In an advantageous variant for determining the transverse sensitivity of a single magnetic field sensor, the electrical conductor is embodied and arranged as a planar coil, in such way that when the coil is viewed from above the magnetic field sensor is arranged in the middle of the coil. In a magnetic field sensor of which the defined direction of sensitivity is parallel to the substrate surface, the coil thus generates a magnetic field component at the location of the sensor which is directed exclusively perpendicularly to this defined direction of sensitivity.

A similar variation may also be created for an arrangement of magnetic field sensors. In this variation as well, the electrical conductor is embodied as a coil, particularly a planar coil. The magnetic field sensors of the arrangement are then arranged inside the coil in such manner that signal portions of magnetic field components of the magnetic field generated by the coil which extend parallel to the defined direction of sensitivity, cancel each other out in the combined output signal. Instead of a single coil, multiple coils may also be used, in a coaxial arrangement for example, which then each enclose a common area in which the magnetic field sensors are arranged as described above.

In another advantageous variant, the magnetic field sensor is arranged between multiple electrical conductors, by which a corresponding magnetic field is generated on the location of the magnetic field sensor. With an exactly symmetrical arrangement of the magnetic field sensor between two conductors, if the magnetic field sensor has a defined direction of sensitivity parallel to the substrate surface it is possible for this magnetic field sensor that only a magnetic field component perpendicular to the defined direction of sensitivity contributes to a measurement signal of the magnetic field sensor. In an asymmetrical arrangement this can also be achieved with different currents through the two electrical conductors. In this case, the currents may be also be applied to the two conductors with a time offset or alternatingly. The measurement signals returned by the magnetic field sensor for each of the two magnetic fields generated one after the other are then added to give a combined measurement signal, to which then only the magnetic field component perpendicular to the defined direction of sensitivity contributes. This applies equally in an arrangement of the magnetic field sensor between two preferably planar electrical coils and can also be transferred to an arrangement consisting of more than two electrical conductors or coils. Moreover, the temporally offset generation of the magnetic fields may also be used to determine the transverse sensitivity of an arrangement of magnetic field sensors which returns an output signal combined from the measurement signals of the magnetic field sensors and has a defined direction of sensitivity. In this case, the output signal is then formed from correspondingly temporally offset measurements.

### BRIEF DESCRIPTION OF THE DRAWINGS

The suggested method and the associated arrangements will be explained in greater detail in the following with reference to exemplary embodiments in conjunction with the drawing. In the drawing:

FIG. 1 shows an example of a variation of the suggested sensor arrangement for determining the transverse sensitivity of a magnetic field sensor;

FIG. 2 shows a second example of a variation of the suggested sensor arrangement for determining the transverse sensitivity of a magnetic field sensor;

FIG. 3 shows an example of a variation of the suggested sensor arrangement for determining the transverse sensitivity of an arrangement of a plurality of magnetic field sensors; and

FIG. 4 shows a further example of a variation of the suggested sensor arrangement for determining the transverse sensitivity of a magnetic field sensor.

### WAYS TO IMPLEMENT THE INVENTION

FIG. 1 shows a first example of a variation of the suggested sensor arrangement for determining the transverse sensitivity of a single magnetic field sensors 1. Magnetic field sensor 1, for example a Hall sensor, is integrated in a substrate 6, and has a defined direction of sensitivity 2. It is intended to use this to detect magnetic field components which occur in this direction of sensitivity 2. In order to be able to determine these magnetic field components in direction of sensitivity 2 as accurately as possible, a possible transverse sensitivity of magnetic field sensor 1 to magnetic field components that are perpendicular to the direction of sensitivity 2 must be known, so that the measurement signal can be corrected appropriately when such magnetic field components perpendicular to the direction of sensitivity 2 are present.

In order to determine transverse sensitivity, in the present example an electrical conductor 3 in the form of a planar coil is arranged around the magnetic field sensor 1 on the surface of substrate 6. When the substrate 6 is viewed from above, magnetic field sensor 1 is located in the middle of said coil. In order to determine the transverse sensitivity of magnetic field sensor 1, a current flow 4 of known magnitude is passed through the coil. The magnetic field generated in this way at the location of magnetic field sensor 1 has a magnetic field component 5 which is aligned exactly perpendicularly to the direction of sensitivity 2 of the magnetic field sensor. At this point, only the perpendicular magnetic field component 5 occurs. The measurement signal generated in magnetic field sensor 2 by this magnetic field component 5 is captured and corresponds to the transverse sensitivity of the magnetic field sensor to the magnetic field component 5 of known strength.

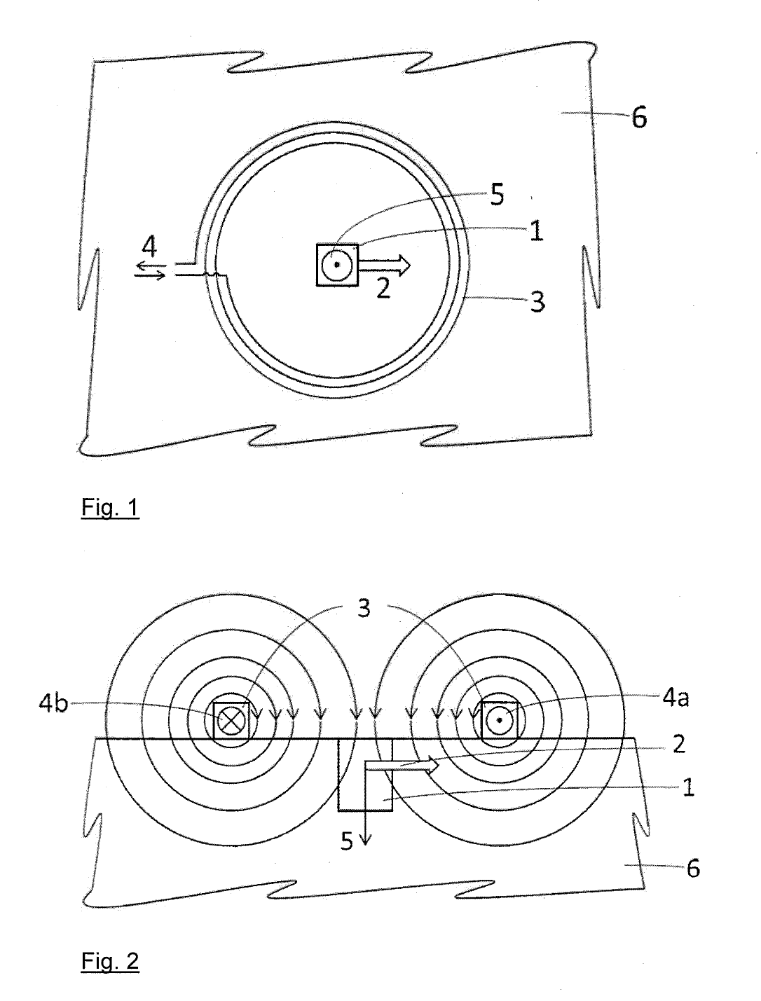

FIG. 2 shows a further example of determining the transverse sensitivity of a magnetic field sensor 1, which is integrated in a substrate 6. In the example of FIG. 2, a sectional view perpendicular to the surface of substrate 6 is shown. The sensor 1 integrated in substrate 6, e.g., a Hall sensor, also has a defined direction of sensitivity 2 parallel to the surface of substrate 6. In this example, the magnetic field for determining the transverse sensitivity is generated by two separate electrical conductors 3, which extend parallel to each other, with magnetic field sensor 1 arranged centrally between them. The two electrical conductors 3 are each exposed individually to a current flow 4a and 4b in opposite directions, as is indicated in FIG. 2. The current flow and therewith the magnetic fields generated by the current flow are known and indicated in the figure by magnetic field lines. A combined magnetic field with a magnetic field component 5 that extends perpendicularly to the direction of sensitivity 2 of magnetic field sensor 1 occurs at the location of sensor 1. Given a corresponding transverse sensitivity, magnetic field sensor 1 only generates a measurement signal in response to this perpendicular magnetic field component 5. The magnetic field components of the magnetic field generated by the two conductors 3 which extend parallel to the direction of sensitivity at the location of magnetic field sensor 1 cancel each other out in the measurement signal of magnetic field sensor 1 in this example. This is therefore another way in which the transverse sensitivity of magnetic field sensor 1 can be determined.

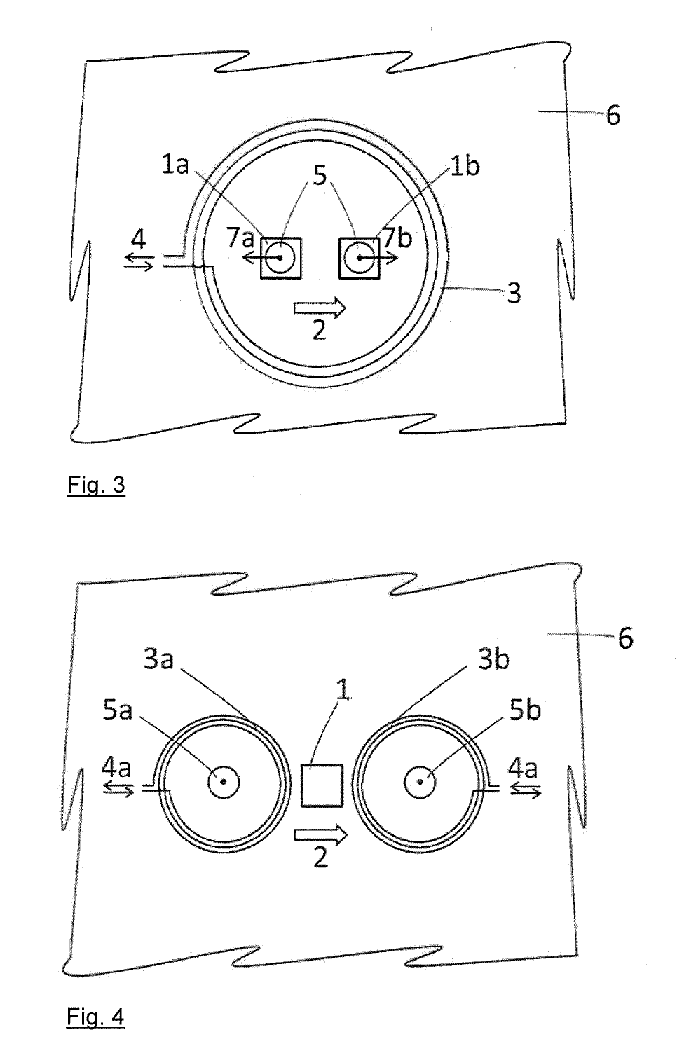

FIG. 3 shows an example of a sensor arrangement consisting of two magnetic field sensors 1a, 1b, which returns the sum of the measurement signals from both single sensors as the output signal and has a defined direction of sensitivity 2. In order to determine transverse sensitivity, here too an electrical conductor 3 shaped in the form of a planar coil is used, and is placed on the surface of substrate 6. The two magnetic field sensors 1a, 1b each have a defined direction of sensitivity which corresponds to the direction of sensitivity 2 of the entire sensor arrangement, and they are integrated in substrate 6. In this case, the coil is arranged relative to the single sensors 1a, 1b in which manner that when the coil is viewed from above they are disposed point symmetrically about the centre of the coil. When a current flow 4 is passed through the coil both magnetic field components 5 perpendicular to the surface of the substrate 6 and magnetic field components 7a, 7b parallel to the surface of substrate 6 are generated at the location of each magnetic field sensor 1a, 1b, as is indicated in FIG. 3. In the sum signal of this sensor arrangement, in which the measurement signals of both magnetic field sensors 1a, 1b are combined by adding them together, the magnetic field components 7a, 7b aligned parallel to the surface are compensated, so that only the magnetic field component 5 aligned perpendicularly to the surface have to be measured, and in this way the transverse sensitivity of the sensor arrangement is determined.

Finally, FIG. 4 shows a further example of a sensor arrangement for determining the transverse sensitivity of a magnetic field sensor. In this example, two electrical conductors 3a, 3b in the form of a coil are used and are arranged on the substrate on either side of magnetic field sensor 1. Magnetic field sensor 1 is again integrated in substrate 6 and has a direction of sensitivity 2 parallel to the surface of the substrate. The two coils generate magnetic fields with perpendicular magnetic field components 5a, 5b that are perpendicular in the centre of the coils, which not only have magnetic field components that are perpendicular to the direction of sensitivity 2 but also magnetic field components parallel thereto at the location of magnetic field sensor 1. These compensate each other mutually in the measurement signal, as in the variation according to FIG. 2. If an arrangement of multiple magnetic field sensors is used instead of the one magnetic field sensor 1, the parallel magnetic field components may also be compensated for a suitable arrangement of the magnetic field sensors and/or coils in similar manner to that of FIG. 3 by combining the measurement signals of the single sensors in the output signal. Currents 4a, 4b through the two coils may be identical, but do not have to be.

Of course, the geometry of the electrical conductors used for generating the magnetic fields and the arrangement thereof relative to the one or more magnetic field sensors may also vary widely from the variations which were explained in the preceding exemplary embodiments. The only essential feature is that with these electrical conductors a magnetic field may be generated at the location of the respective magnetic field sensors, by means of which the transverse sensitivity of the magnetic field sensor or the arrangement of magnetic field sensors is measurable.

### LIST OF REFERENCE SIGNS

1,1a,1b Magnetic field sensor with defined direction of sensitivity
2 Defined direction of sensitivity
3,3a,3b Electrical conductor
4,4a,4b Current flow
5 Magnetic field component perpendicular to the direction of sensitivity
6 Substrate
7a,7b Magnetic field component parallel to the direction of sensitivity

1. Method for determining the transverse sensitivity of a magnetic field sensor, which has a defined direction of sensitivity and is arranged on a substrate or integrated in a substrate, in which
one or more electrical conductors which generate a magnetic field when current flows are applied on the substrate and/or integrated in the substrate,
wherein the one or more electrical conductors are arranged and embodied in such manner that they generate one or more magnetic fields at the location of the magnetic field sensor, which either only has/have one magnetic field component perpendicular to the defined direction of sensitivity or of which only one magnetic field component perpendicular to the defined direction of sensitivity contributes to a measurement signal or combined measurement signal of the magnetic field sensor, and
the measurement signal induced by the magnetic field component perpendicular to the defined direction of sensitivity is captured in the magnetic field sensor to obtain the transverse sensitivity of the magnetic field sensor.

2. Method for determining the transverse sensitivity of an arrangement of magnetic field sensors which are arranged on a substrate and/or integrated in a substrate, wherein the arrangement returns an output signal combined from measurement signals of the magnetic field sensors and has a defined direction of sensitivity, in which
one or more electrical conductors, which generate a magnetic field upon the application of a current flow are applied on the substrate and/or integrated in the substrate,
wherein the one or more electrical conductors are arranged and embodied in such manner that they generate one or more magnetic fields at the locations of the magnetic field sensors, of which only one magnetic field component perpendicular to the defined direction of sensitivity contributes to the output signal of the arrangement, and
the output signal induced in the arrangement by the magnetic field component perpendicular to the defined direction of sensitivity is captured to obtain the transverse sensitivity of the arrangement.

3. Method according to claim 2,
characterized in that
the output signal generated in the arrangement by the magnetic field component perpendicular to the defined direction of sensitivity is captured for a different current flow through the one or more electrical conductors, in order to capture the transverse sensitivity for different strengths of the magnetic field component perpendicular to the defined direction of sensitivity.

4. Method according to claim 2,
characterized in that
the one or more electrical conductors are embodied as one or more coils, particularly planar coils.

5. (canceled)

6. Method according to claim 4,
characterized in that
the one or more coils are embodied and arranged in such manner that they enclose a common area in which the magnetic field sensors of the arrangement of magnetic field sensors are disposed.

7. (canceled)

8. Sensor arrangement with at least one magnetic field sensor, which has a defined direction of sensitivity and is arranged on a substrate and/or integrated in a substrate,
in which one or more electrical conductors, which generate a magnetic field when a current flow is applied are arranged on the substrate and/or integrated in the substrate,
wherein the one or more electrical conductors are arranged and embodied in such manner that they can generate one or more magnetic fields at the location of the magnetic field sensor when a current flow is applied, which either have only one magnetic field component perpendicular to the defined direction of sensitivity or of which only one magnetic field component perpendicular to the defined direction of sensitivity contributes to a measurement signal or combined measurement signal of the magnetic field sensor.

9. Sensor arrangement with multiple magnetic field sensors, with which an output signal combined from measurement signals of the magnetic field sensors can be created, for which it has a defined direction of sensitivity, in which
the magnetic field sensors are arranged on a substrate and/or integrated in a substrate and
one or more electrical conductors, which generate a magnetic field when a current flow is applied, are arranged on the substrate and/or integrated in the substrate,
wherein the one or more electrical conductors are arranged and embodied in such manner that they can each generate one or more magnetic fields at the locations of the magnetic field sensors when current flows are applied, of which only one magnetic field component perpendicular to the defined direction of sensitivity contributes to the output signal.

10. Sensor arrangement according to claim 8,
characterized in that
the one or more electrical conductors is/are embodied as one or more coils, particularly planar coils.

11. Sensor arrangement according to claim 10,
characterized in that
the magnetic field sensor is arranged in the centre of the coil.

12. (canceled)

13. Sensor arrangement according to claim 8,
characterized in that
a plurality of the electrical conductors are disposed on both sides of the one magnetic field sensor field.

14. Sensor arrangement according to claim 8,
characterized in that
the magnetic field sensor is a Hall sensor.

15. Sensor arrangement according to claim 9,
characterized in that
the one or more electrical conductors is/are embodied as one or more coils, particularly planar coils.

16. Sensor arrangement according to claim 15,
characterized in that
the one or more coils enclose a common area in which two or more magnetic field sensors are arranged in such manner that signal portions of magnetic field components of the magnetic field generated by the coil(s) which extend parallel to the defined direction of sensitivity at the location of the magnetic field sensors cancel each other out in the combined output signal.

17. Sensor arrangement according to claim 9,
characterized in that
a plurality of the electrical conductors are disposed on both sides of the magnetic field sensors.

18. Sensor arrangement according to claim 9,
characterized in that
the magnetic field sensors are Hall sensors.

19. Method according to claim 1,
characterized in that
the measurement signal generated in the magnetic field sensor by the magnetic field component perpendicular to the defined direction of sensitivity is captured for a different current flow through the one or more electrical conductors, in order to capture the transverse sensitivity for different strengths of the magnetic field component perpendicular to the defined direction of sensitivity.

20. Method according to claim 1,
characterized in that
the one or more electrical conductors are embodied as one or more coils, particularly planar coils.

21. Method according to claim 20,
characterized in that
the coil is embodied and arranged in such manner that the magnetic field sensor is arranged in the centre of the coil.
